(19) United States
(12) Patent Application Publication
(10) Pub. No.: US 2007/0240825 A1
(43) Pub. Date: Oct. 18, 2007

(54) Wafer processing apparatus capable of controlling wafer temperature

(76) Inventors: Seiichiro Kanno, Kokubunji (JP); Manabu Edamura, Kokubunji (JP); Ryujiro Udo, Kokubunji (JP); Masatsugu Arai, Kokubunji (JP); Junichi Tanaka, Kokubunji (JP); Saburo Kanai, Kudamatsu (JP); Ryoji Nishio, Kudamatsu (JP); Tsunehiko Tsubone, Kudamatsu (JP); Toru Aramaki, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/812,289

(22) Filed: Jun. 18, 2007

Related U.S. Application Data
(62) Division of application No. 10/927,095, filed on Aug. 27, 2004.

(51) Int. Cl. H01L 21/306

(52) U.S. Cl. 156/345.27

(57) ABSTRACT

In a wafer processing apparatus, wafers are sequentially placed one by one on a ceramic plate of a wafer stage within a vacuum chamber. The pressure of a heat-conductive gas introduced at this time between the wafer and the ceramic plate is adjusted to control the temperature of the wafer, and the wafer is processed by use of plasma. In this case, the user can select any one of a process for regulating the pressure of the heat-conductive gas each time the wafers are sequentially placed on the wafer stage, a process for optimizing aging conditions, and a process for optimizing heater conditions so that the wafer temperature variation within lot can be reduced by performing the selected process. The selected process is performed on the basis of its conditions that are computed to determine by a control-purpose computer of the processing apparatus.

### CROSS-REFERENCE TO RELATED APPLICATION

This application is a Divisional application of application Ser. No. 10/927,095, filed Aug. 27, 2004, the contents of which are incorporated herein by reference in their entirety.

### BACKGROUND OF THE INVENTION

The present invention generally relates to techniques for etching semiconductor wafers, and particularly to a wafer processing apparatus of the system for continuously processing semiconductor wafers.

Recently, as the semiconductor integrated circuit density increases, the circuit patterns formed in the semiconductor wafer have so far been entirely gone forward miniaturization and up to the point where the dimensional precision is required to be much stricter than ever. In this situation, the temperature management for the wafers (semiconductor wafers) during the process becomes extremely important.

For example, in the etching process required for the patterns to have a high aspect ratio, an organic polymer is actually used to protect the sidewalls of the patterns to thereby achieve anisotropic etching.

At this time, since the organic polymer serving as the protective film is changed in its generation condition by temperature, the temperature of the wafer that is being etched greatly affects the etching rate and the shape of the pattern's sidewalls.

When plasma is used to process wafers, a bias voltage is usually applied to the wafer to accelerate ions by electric field and to draw the ions to the wafer, thus achieving an anisotropic shape. At this time, the wafer is heated to change (increase) its temperature.

Thus, since the temperature management is necessary for the wafer, it is practiced that an electrostatic chuck is used at the stage, and that a heat conductive gas such as helium is introduced into the space between the absorbed wafer and the stage to control the temperature. In this case, a refrigerant that is controlled in its temperature by an external temperature controller is circulated to cool the stage.

However, when the wafers are actually continuously processed, the stage temperature is also unavoidably raised. In this situation, as the number of wafers to be processed increases, the average wafer temperature of wafers during the process also increases. Thus, the etching results will be supposed to change for the above reasons.

In the recent semiconductor manufacturing process, however, the wafer is large-sized in its diameter in order to reduce the manufacturing cost, and thus it is more heated. In addition, the biasing power tends to increase for the purpose of raising the etching rate.

For example, in a process line for 300-mm diameter wafers, the biasing power to be applied to the wafer to etch the interlayer insulating films reaches about 3 kW.

Thus, various methods have so far been proposed for managing the temperature of the wafers during the process. In one example of those methods, the wafer temperature is changed by changing the pressure of the cooling gas against the rear side of a silicon wafer during the process that has silicon layers laminated on a poly silicon layer, as disclosed in JP-A-6-124916.

### SUMMARY OF THE INVENTION

The prior art described in the above JP-A-6-124916 does not consider the point that the wafers are continuously processed in turn, and it has the drawback that the temperature variation between the wafers cannot be reduced.

That is, in the prior art, the temperature variation can be reduced during the time in which each wafer is being processed, but it cannot be reduced over the wafers that are sequentially processed. Therefore, in the actual process line, the wafers even within the same lot, for example, the first wafer and the twenty-fifth wafer, most probably have different etching results, thus causing a trouble.

It is a first objective of the invention to provide a wafer processing apparatus arranged to be capable of suppressing the wafer temperature variation when wafers are continuously processed in turn.

To achieve the above first objective, the temperature of the wafer stage is measured during the process, and the pressure of the cooling gas against the rear side of each of the sequentially processed wafers is changed on the basis of the measured results.

Also, to achieve the above first objective, the temperature of the wafer stage is measured during the process, and the temperature of a refrigerant for cooling the wafer stage is changed for each of the sequentially processed wafers on the basis of the measured results.

In addition, to achieve the above first objective, the temperature of the wafer stage is measured during the process, and the power supplied to the heater to heat the wafer stage is changed for each of the sequentially processed wafers on the basis of the measured results.

According to the invention, since the wafer temperature variation can be reduced within the lot, wafers can be processed with high reproducibility even when the invention is applied to the process having great temperature dependence.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross-sectional view of one embodiment of a wafer processing apparatus according to the invention.

FIG. 2 is a diagram showing the temperature variation within the lot in the prior art.

FIG. 3 is a flowchart to which reference is made in explaining the process for adjusting the pressure of helium He against the rear side of the wafer in the embodiment of the invention.

FIG. 4 is a diagram showing the temperature variation within the lot adjusted for the He-gas pressure against the rear side in the embodiment of the invention.

FIG. 5 is a flowchart to which reference is made in explaining the optimization of the aging conditions according to the embodiment of the invention.

FIG. 6 is a diagram showing the temperature variation within the lot optimized for the aging conditions in the embodiment of the invention.

FIG. 7 is a partially cross-sectional view of another embodiment of a wafer processing apparatus according to the invention.

FIG. 8 is a flowchart to which reference is made in explaining the optimization of the heater conditions in the other embodiment of the invention.

FIG. 9 is a diagram showing the temperature variation within the lot optimized for the heater conditions in the other embodiment of the invention.

FIG. 10 is a diagram to which reference is made in explaining one example of a menu picture in the above embodiments of the invention.

FIG. 11 is a diagram showing a method of fixing a sheathed thermo couple for monitoring the temperature of a ceramic plate in the above embodiments of the invention.

### DETAILED DESCRIPTION OF THE EMBODIMENTS

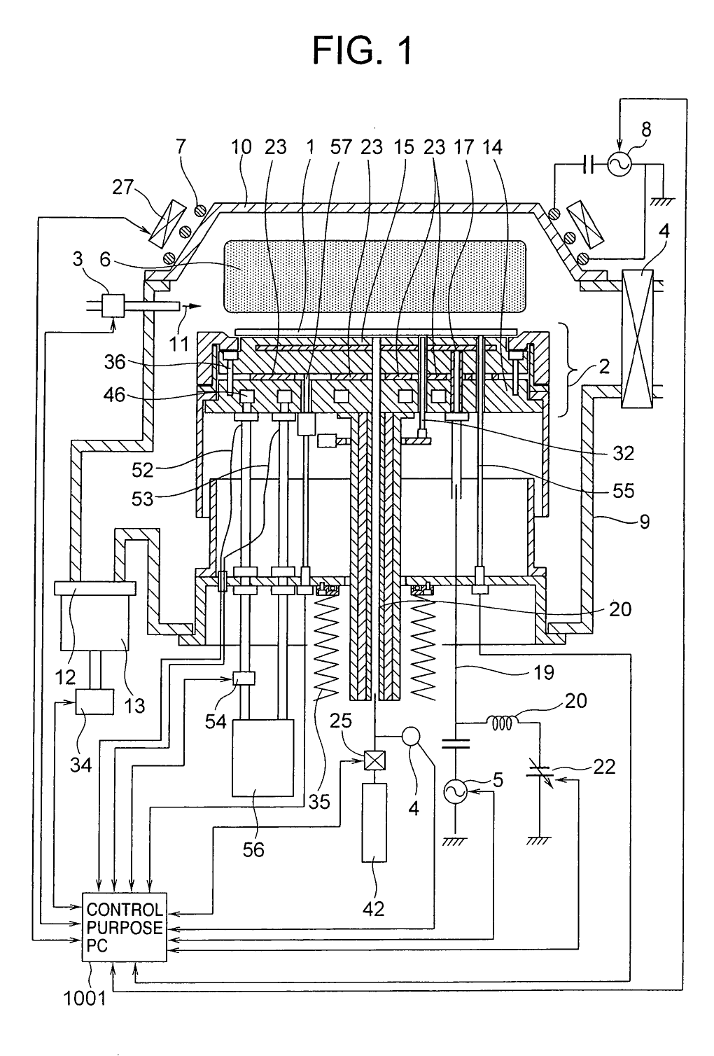

An embodiment of a wafer processing apparatus according to the invention will be described in detail with reference to the drawings. FIG. 1 shows one example of the etching apparatus to which this embodiment of the invention is applied.

Referring to FIG. 1, a wafer 1 is placed on a wafer stage 2 within a vacuum chamber 9. At this time, a bell jar 10 made of aluminum is secured to the top of the vacuum chamber 9 to keep the inside airtight.

The inside of the vacuum chamber 9 is evacuated by a turbo-molecular pump 13 and an oil-less pump 34, and then an etching gas 11 is introduced while it is being controlled in its flow rate by the flow controller 3. At this time, the inside of the vacuum chamber 9 is kept at a proper pressure by adjusting the opening valve travel of a valve 12 provided on the upstream of the turbo-molecular pump 13.

A coil 7 is provided to surround the bell jar 10, and a high-frequency voltage of, for example, 13.56 MHz is supplied to this coil 7 from a high-frequency power supply 8 so that a plasma 6 is generated within the vacuum chamber 9 by inductive coupling.

At this time, a plurality of fans 27 are mounted around the bell jar 10 to keep the bell jar 10 at a constant temperature. Under this condition, the wafer 1 is exposed to the plasma 6 thereby to be etched, while a fluorescent temperature gauge 55 monitors the temperature of wafer 1 during the etching.

Moreover, in order to apply a bias voltage to the wafer 1 at this time, a high-frequency power supply 5 is connected through a feed line 19 to the wafer stage 2. In addition, to this feed line 19 is connected a DC power supply 22 through a high-frequency choke coil 21. Thus, the electrostatic chuck function is provided to the wafer stage 2 in order to absorb and hold the wafer 1.

At this time, the wafer stage 2 has heat-conductive sheets 23 fixedly mounted between a ceramic plate 15 and a cooling jacket 14 for cooling that are held fixed with bolts 36. This ceramic plate 15 is made of aluminum nitride, and has the above electrostatic chuck function.

Reference numeral 4 represents a gate valve, which opens when the wafer 1 is carried into the vacuum chamber 9 from the outside or carried from the vacuum chamber 9 to the outside, thus making it possible that the arm (not shown) for carrying the wafer 1 is moved forward or back.

Reference numeral 32 denotes a pusher pin, which functions to make the wafer 1 be attached to or detached from the stage 2. A bellows 35 is elastically expanded and contracted by a vertically moving mechanism (not shown) so as to move the whole wafer stage 2 up and down, thereby making it possible that the carrying arm catches and releases the wafer 1.

In addition, flow channels 46 for allowing the refrigerant to pass are provided within this cooling jacket 14. The refrigerant is supplied to the flow channels 46 from an external circulator 56, thereby cooling the cooling jacket 14.

At this time, a flowmeter 54 measures the flow of the refrigerant, thermocouples 52, 53 measure the temperatures of the inlet and outlet sides of the circulator 56, and a control-purpose computer (control-purpose PC) 1001 monitors the measurements and controls the temperature of wafer 1 to keep at a predetermined value. The control-purpose computer 1001 is connected to sensors, a flow controller, power supplies etc. (that is, a flow controller 3, the high-frequency power supplies 5, 8, the DC power supply 22, a pressure gauge 24, a flowmeter 25, the oil-less pump 34, the thermocouples 52, 53, 57, the flowmeter 54 etc.) as shown in FIG. 1 and receives outputs therefrom thereby to detect operating statuses of these elements (that is, the sensors, the flow controller, the power supplies etc.) and the wafer processing apparatus (etching apparatus) and then outputs at least one operation control command to the corresponding one (ones) of these elements based on the detected operation statuses so as to adjust the operation of the corresponding one (ones) of these elements.

In addition, the ceramic plate 15 has an internal electrode 17 buried inside that provides the electrostatic chuck function and an RF (radio frequency) bias to the wafer stage 2.

Thus, application of a DC voltage to this internal electrode 17 will induce a potential difference between the internal electrode 17 and the wafer 1 (that is substantially at earth potential when exposed to the plasma) so that electric charges are stored between the internal electrode 17 and the rear side of the wafer 1. As a result, a Coulomb's force is generated to cause the wafer 1 to be absorbed to the ceramic plate 15, thus fixed to the wafer stage 2.

The DC voltage for electrostatic chuck at this time is supplied from the DC power supply 22 through the coil 21 to the feed line 19.

Moreover, if a high-frequency voltage is applied to the internal electrode 17, a bias voltage can be applied to the wafer 1. Consequently, we can expect the effects that the ions in the plasma are effectively pulled in to increase the etching rate and to improve the etched shape.

At this time, the above-mentioned fluorescent temperature gauge 55 is inserted in the through-holes that are bored in the cooling jacket 14 and ceramic plate 15 at the same position, and fixed so that its tip is made in contact with the rear side of the wafer 1. While the fluorescent temperature gauge is used in this embodiment, a radiation thermometer or sheathed thermocouple, for instance, may be used according to the temperature range to be measured.

In addition, the number of positions at which the temperature is measured is not limited to one as illustrated. For example, if the temperature is measured at three different points in the radius direction, detailed information of the wafer temperature distribution can be obtained.

Although providing more points of measurement will result in acquisition of more detailed temperature information, an appropriate number of points are selected according to need because provision of more points leads to high cost and difficulty with mounting.

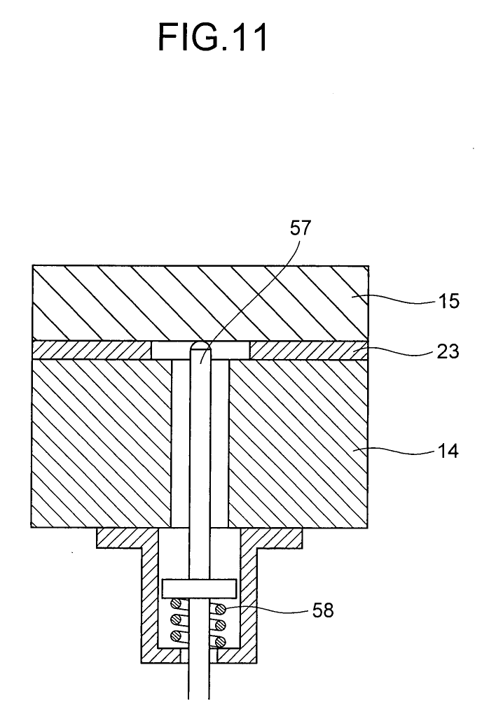

Also, the same through-hole as in the fluorescent temperature gauge 55 is provided in the cooling jacket 14, and a sheathed thermocouple 57 is inserted in this through-hole up to the point where its tip can be made in contact with the rear side of the ceramic plate 15. This sheathed thermocouple 57 monitors the temperature of the wafer stage 2 during the process. If the sheathed thermocouple 57 and the wafer stage 2 are unstably made in contact, the measurement precision is degraded. Thus, in this embodiment, in order that the contact condition can be always constant, the sheathed thermocouple 57 is pushed against the ceramic plate 15 by use of a spring structure 58 as shown in FIG. 11. The results of the measurement under this construction are transmitted to the computer that manages the processing apparatus.

While a single measurement point for the temperature is provided in this embodiment, the number of measurement points may be increased if necessary. If the temperature is measured at a plurality of points, we can early realize that a trouble occurs if one of the thermocouples set at the points fails for some reason. Thus, a deep trouble can be prevented from occurring for this reason.

However, since increasing the number of measurement points will cause problems such as high cost and complication of mounting structure, the number of measurement points is determined properly according to need.

In addition, a heat-conductive gas such as helium gas is introduced into the space between the rear side of wafer 1 and the ceramic plate 15 so that the heat input to the wafer 1 can be effectively conducted to the wafer stage 2. Thus, the temperature of wafer 1 can be suitably controlled.

This helium gas is supplied from a gas container 42 through a hollow shaft 20, while the pressure gauge 24 and the flowmeter 25 are monitoring the pressure and flow rate of the helium gas.

Incidentally, the etching apparatus shown in FIG. 1 has a control unit (not shown) to control the whole processing operations. This control unit includes a PC (personal computer) in which a “program for reducing the temperature variation within lot” is stored. This program is executed to perform certain processes, or to operate the etching apparatus.

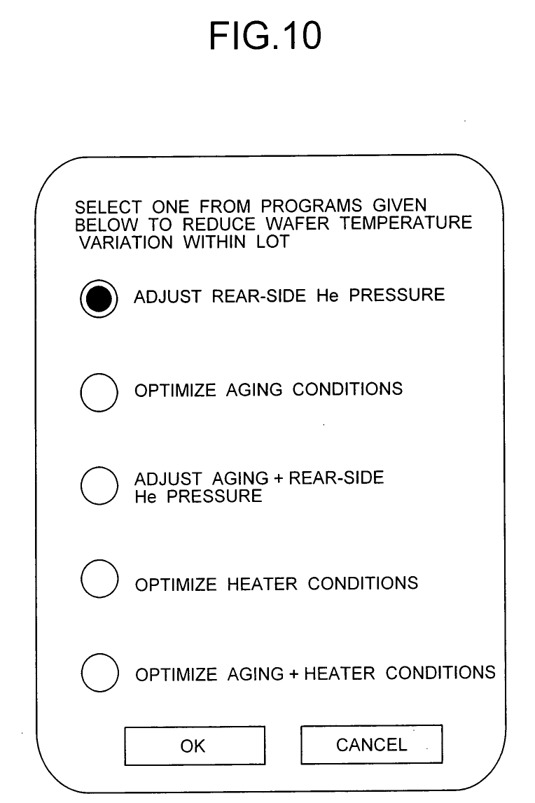

At this time, this embodiment provides a plurality of different programs as “program for reducing the temperature variation within lot”, each of which the user can select so that a process can be performed according to the selected program. Thus, the control unit displays a menu picture 100 shown in FIG. 10, from which the user can arbitrarily select a necessary process.

Since this function of “program for reducing the temperature variation within lot” is required not to operate if the user does not need, this menu has an option not to operate the function of “program for reducing the temperature variation within lot”.

This menu 100 is displayed only when the user selects the “program for reducing the temperature variation within lot” through an input interface not shown.

In this embodiment, the following five different programs each of which can be selected are provided as the “program for reducing the temperature variation within lot” as shown in FIG. 10. The programs are, respectively, to

Adjust rear-side He pressure,

Optimize aging conditions,

Adjust aging+rear-side He pressure,

Optimize heater conditions, and

Optimize aging+heater conditions.

More details will be described later.

Incidentally, when the wafer 1 is processed with a bias voltage applied, the temperature of wafer 1 is raised since the plasma heats it as described above. Although a small amount of heat transmitted to the wafer 1 will sometimes cause no problem, the ordinary semiconductor manufacturing process might incur poor etching characteristics if the temperature of wafer was not strictly managed as described above.

Therefore, the management of wafer temperature is extremely important, and thus the wafer temperature as the point of this invention will be described in detail with the invention compared with the case in which this invention is not applied.

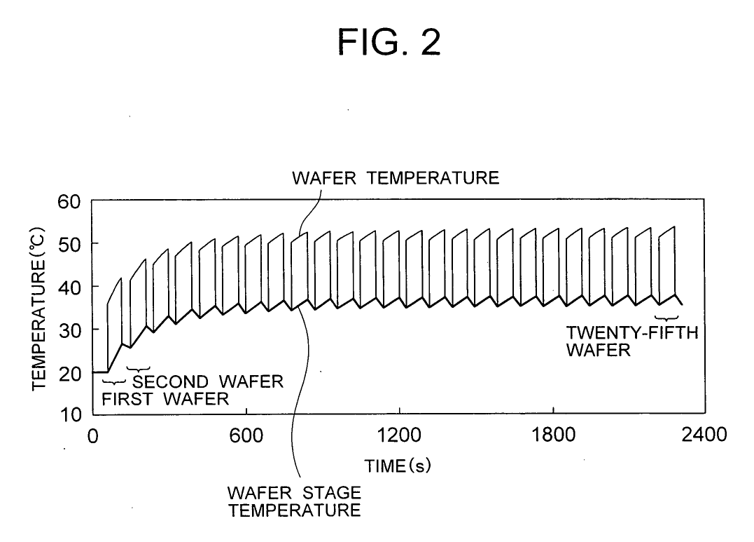

FIG. 2 is a diagram showing an example of the average variations of the wafer stage temperature and the temperature of the wafer processed under the conventional conditions without application of this invention. In this example, the oxide film of the wafer was etched.

The etching conditions used at this time are as follows. A mixture gas of argon and C₄F₈ was used as an etching gas, and the pressure of the etching gas was 1.0 Pa. The plasma source power was 1 kW, and the biasing power was 1.5 kW. A fluorocarbon refrigerant was used for cooling the wafer stage 2, and the flow rate of the refrigerant was 3 L/min. It was set at a temperature of 20° C.

The etching time was 60 seconds, and the waiting time between the preceding and following wafers was 30 seconds. At this time, the rear-side He pressure (the pressure of helium gas against the rear side of wafer 1) was kept at 1 kPa over all wafers from the first to last twenty-fifth one.

From the characteristics shown in FIG. 2, it will be understood that the average temperature of the first wafer just before the end of the process was 42.3° C., but that of the twenty-fifth wafer was 52.6° C., which was a great change. Particularly, the average temperatures of the first to fifth or sixth wafer are greatly changed. At this time, the wafer stage temperature was also changed from 26.4° C. to 36.7° C.

At this time, the rear-side He pressure was kept at 1 kPa as described above, and thus the temperature difference between the ceramic plate 15 and each wafer is seen to be substantially constant over the first to twenty-fifth wafers. Therefore, it will be understood that the change of the wafer temperature is caused by the increase of the temperature of ceramic plate 15.

Thus, the conventional apparatus cannot maintain the wafer temperature to be constant even if the rear-side He pressure is controlled constant. Since the etching characteristics are generally affected by temperature as described above, this temperature change affects the etching effect.

Thus, in this embodiment of the invention, the average temperature of each wafer is maintained constant over all the wafers by allowing for the increase of the wafer temperature due to the temperature rise of the wafer stage. This embodiment will be further described in detail.

If, now, the user selects the “program for reducing the temperature variation within lot”, the menu picture 100 of FIG. 10 is displayed, or a list of methods for adjusting the wafer temperature appears.

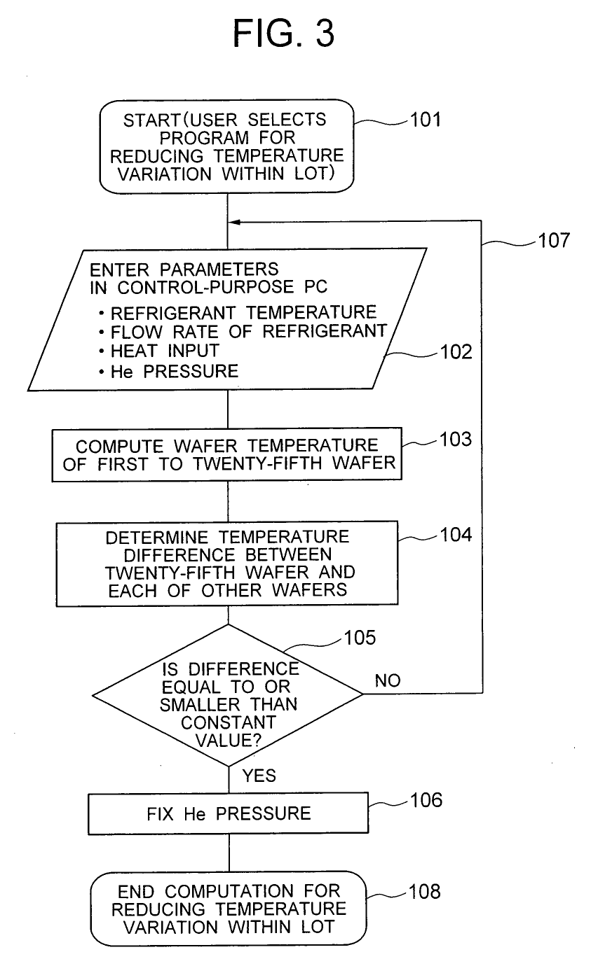

It is here assumed that the user selects “Adjust rear-side He pressure” on the menu picture 100 shown in FIG. 10. Then, in this process of “Adjust rear-side He pressure”, the rear-side He pressure is changed for each wafer so that the average temperature of each wafer can be made constant over all the wafers. In this case, the above-mentioned control unit (control-purpose PC) goes to the execution of the process according to the flowchart shown in FIG. 3.

When the process shown in FIG. 3 is selected (step 101), parameters necessary for computation are entered in the control-purpose PC (step 102).

The parameters entered at this time are parameters that affect the wafer temperature, or amount of heat input, He pressure, heat capacity of electrostatic chuck (ceramic plate 15), refrigerant temperature, flow rate of refrigerant, and kind of refrigerant. In this case, the He pressure stands for the rear-side He pressure. The above parameters will be described later.

In this embodiment, the amount of heat input can be calculated from the measurements of the refrigerant flow rate and the temperatures of refrigerant (cooling medium) at its inlet and outlet. In this case, the refrigerant flow rate is taken from the flowmeter 54, and the temperatures of the refrigerant at its inlet and outlet from the thermocouples 52, 53, respectively.

On the other hand, if the percentage of the heat input to the biasing power is previously grasped by experiment, the amount of heat input can be estimated without the actual measurement. In this case, the He pressure can be set for any value that the user decides to be appropriate.

Here, this He pressure can be taken from the pressure gauge 24, and the heat capacity of the ceramic plate 15 can be easily fixed to a value because it is not generally frequently changed once it is decided though it depends on the change of its structure.

At this time, the user arbitrarily fixes the refrigerant temperature. Since the user is generally not much aware of the flow rate of the refrigerant, the flow rate of the refrigerant is monitored by the flowmeter 54 and observed by the control-purpose PC in this embodiment.

The flow rate of the refrigerant is not often changed once the structure of the apparatus is decided. Therefore, in this case, it can be determined without monitoring.

In addition, although the kind of the refrigerant is used as a parameter because the viscosity of the refrigerant affects the temperature, the kind is not changed once it is decided.

Accordingly, in step 102, data of each of the refrigerant temperature, refrigerant flow rate, amount of heat input and rear-side He pressure is entered in the control-purpose PC. Then, the wafer temperatures of the first to twenty-fifth wafers are computed by the control-purpose PC on the basis of this information (data) (step 103).

This computation is not necessarily made by the control-purpose PC, but may be performed by another different PC externally provided.

At this time, if a function is provided to display the results of the computation on a monitor, the usability is improved. In addition, a function can be provided to select if the following computation is made on the basis of the displayed results. This function is convenient because the operator can decrease the time to waste in unnecessary computation.

Then, since the average temperature of each wafer increases as the wafers are sequentially processed from the first to twenty-fifth wafers unless the processing conditions are changed, the differences between the temperature of the twenty-fifth wafer and the temperature of each of the other wafers (temperature difference) is determined (step 104).

At this time, it is not always necessary to compare to the twenty-fifth wafer. For example, when it is clear that the wafer temperature of the tenth wafer is already the same as that of the twenty-fifth wafer, the temperature of each wafer may be compared with that of the tenth wafer.

Next, judgment is made of whether this temperature difference is fallen within a predetermined reference value (that is, equal to or smaller than the predetermined value) (step 105). At this time, while this embodiment uses 0.5° C. as the reference value in view of the required etching performance, the reference value is not limited to this value.

In addition, this reference value may be previously stored in the PC or appropriately fixed any time by the user.

If the temperature difference is fallen within the reference value without adjusting the He pressure, or if the judgment result in step 105 is Y (affirmative), the program goes to step 106, where the conditions of rear-side He pressure are decided for the first to twenty-fifth wafers.

If the temperature difference exceeds the reference value, or if the judgment result in step 105 is N (negative), the program goes back to step 102, from which the rear-side He pressure for each wafer is again newly set, and the wafer temperatures and temperature differences are again calculated in turn (steps 102, 103, 104).

If all the temperature differences are finally fallen within the reference value after the repetition of this operation, the rear-side He pressures are fixed in step 106, and the program for this “Adjust rear-side He pressure” is finished (step 108).

The computation procedure for determining the rear-side He pressures will be described next, which has first and second methods.

The first method is a method for computing the rear-side He pressure for each wafer. If, now, the difference between the temperatures of the first and twenty-fifth wafers is higher than the reference value, the rear-side He pressures of the second and following wafers are left as previously set by the user, but only that of the first wafer is altered to be lower. This operation is repeated. First, the temperature difference of the first wafer to the twenty-fifth wafer is made to be fallen within the reference value.

Next, the rear-side He pressures of the third and following wafers are left as previously set by the user, but that of the second wafer is this time altered to be lower as is the He pressure of the first wafer. This operation is thus repeated. Thus, the temperature difference of the second wafer to the twenty-fifth wafer is made to be fallen within the reference value.

If this operation is repeated until the twenty-fourth wafer, the temperature variation can be suppressed over the first to twenty-fifth wafers. At this time, if the temperature difference between the twenty-fifth wafer and a wafer a few ones after is fallen within the reference value, the He pressures of the following wafers are not required to change.

In the second method, when the rear-side He pressure of the first wafer is decided in the above first method, an asymptotic equation for the rear-side He pressures of up to the twenty-fifth wafer is computed from that of the first wafer, and the rear-side He pressures of the second and following wafers are estimated from this equation.

For example, if Pu and P1 respectively represent the He pressure of the first wafer fixed by the user and that computed, the He pressure P (N) of Nth wafer can be computed from the following equation (1) where τ is constant.
P(N)=P1+(Pu−P1)(1−exp(−(N−1)/τ)) (1)

According to this equation (1), the He pressures of the first to twenty-fourth wafers can be determined at a time if only the constant τ is decided. Thus, the computing time can be saved.

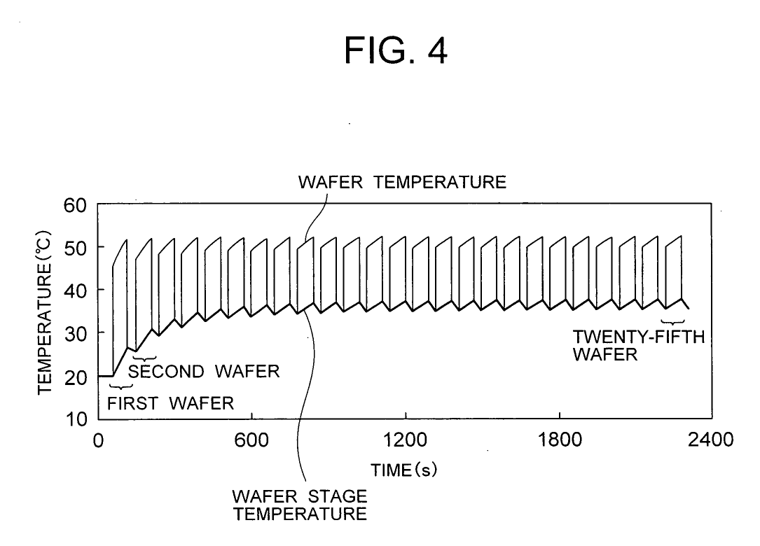

FIG. 4 shows the temperature of each wafer after processing wafers according to the program shown in FIG. 3. From FIG. 4, it will be seen that the temperature of the wafer stage gradually increases as in the prior art, but the temperatures of the first and twenty-fifth wafers just before the end of processing are 52.8° C., and 52.6° C., respectively. That is, the temperatures of all wafers are substantially constant.

Therefore, according to this embodiment, the temperatures of all wafers can be made substantially constant by processing according to the program shown in FIG. 3 and adjusting the He pressure (rear-side He pressure). As a result, when the wafers are sequentially processed, reproducible etching can be achieved.

In order to actually process wafers on this construction, it is important to monitor the wafer temperature or wafer stage temperature. In other words, although a computer determines the temperatures of the wafers and wafer stage, the results of the computation are required to check if they coincide with the actual measurements in order that the reliability of the apparatus can be increased. For this purpose, this embodiment uses the fluorescent temperature gauge to measure the rear-side temperature of each wafer, and the sheathed thermocouples to measure the wafer stage temperature. The results of the measurements are transmitted to the control-purpose computer, where they are compared with the results of the computation.

While computation of temperature is made each time the user sets in order to determine the rear-side He pressure in the above embodiment, the user is not always required to compute, but a conversion table of the combinations of amounts of heat input and rear-side He pressures may be previously stored in the control-purpose computer so that a combination of an amount of heat input and the rear-side He pressure of each wafer can be selected from the conversion table in accordance with the user's setting.

In addition, while only a single kind of program is used for each wafer in this embodiment, a plurality of programs may be combined and used.

While the PC automatically calculates the rear-side He pressures in this embodiment, the operator may arbitrarily manually set the He pressures. In this case, the usability for the operator is improved.

In this embodiment, the data of the wafer stage temperatures measured by the sheathed thermocouples is used to monitor whether the results of the computation are correct. However, this temperature data may be used to control the rear-side He pressures, thereby adjusting the wafer temperatures. This case will be described below.

The wafer stage temperatures measured by the sheathed thermocouples that depend on the measurement positions are substantially the same as the temperature of the surface of the wafer stage shown in FIG. 2. From FIG. 2, it will be seen that the rise of the average temperature of wafer with the increase of the number of processed wafers is caused by the temperature rise of the wafer stage. Thus, this temperature rise is cancelled out by adjusting the He pressure against the rear side of each wafer so that the temperature difference between the wafer stage and each wafer can be reduced, thereby flattening the average temperatures of all wafers.

In other words, since this embodiment also uses the fluorescent temperature gauge to monitor the wafer temperature, it can determine the wafer stage temperature and the temperature difference between the wafer stage and each wafer. Since the temperature of the wafer stage just before the second wafer is started to process after the end of the first wafer processing is measured by the sheathed thermocouples, the difference between the wafer stage temperature just before the second wafer is started and that just before the first wafer is started to process can be determined. Therefore, in order that the temperature of the second wafer can be made equal to that of the first wafer, the temperature difference between the second wafer and the wafer stage just before the second wafer is started to process is required to determine by subtracting the wafer stage temperature just before the second wafer is started to process from the wafer temperature just after the first wafer is processed. The rear-side He pressure necessary for this temperature difference can be calculated from the relation between the He pressure and thermal conductivity that is previously provided in the control-purpose computer. Accordingly, the average temperature of the second wafer can be made equal to that of the first wafer by processing the second wafer under this calculated He pressure. For the third and following wafers, the same procedure is used to adjust the He pressure, thereby reducing the temperature variation of the wafers.

This embodiment has treated the temperature measured on the rear side of the wafer stage as the typical temperature. This method can be said to be simple and easy when the thermal conductivity is large and when the temperature gradient does not occur in the thickness direction. However, when the material has a small thermal conductivity or when the amount of heat input is large enough to cause a temperature gradient in the thickness direction, the temperature difference between the surface and rear side of the wafer stage becomes large. Thus, the temperature of the rear side of the wafer stage will be sometimes inadequate for the typical temperature. In such case, if the control-purpose computer corrects the measured temperature data, the same function can be achieved, and thus the same effect can be expected.

In addition, while the temperatures of wafers were measured in this method, they are not always required to measure. In other words, since the amount of heat input to the wafer during process and the thermal conductivity of He gas are known by the measurement or computation, the wafer temperature can be predicted by computation. Therefore, using this temperature and the measured temperature of the ceramic plate will enable the same processing to be made. In this case, since the fluorescent temperature gauge is never made in direct contact with the rear side of each wafer, we can expect the effect that any foreign material is never attached to the rear side of each wafer.

Then, it is assumed that after selecting the “program for reducing temperature variation within lot”, the user this time selects the process to “Optimize aging conditions” from the menu picture 100 of FIG. 10.

In this process of “Optimize aging conditions”, just before processing the lot, an aging process is performed to optimize the wall temperature and surface condition of the vacuum chamber. Before the wafers are started to process, the wafer stage is previously heated from the plasma as the aging process so that the wafer temperature variation within the lot can be reduced.

In this case, however, if the heat from the plasma is too high and continued to apply too long or makes aging too long, the temperature of the first wafer, of course, becomes too high, thus needing to optimize the aging time.

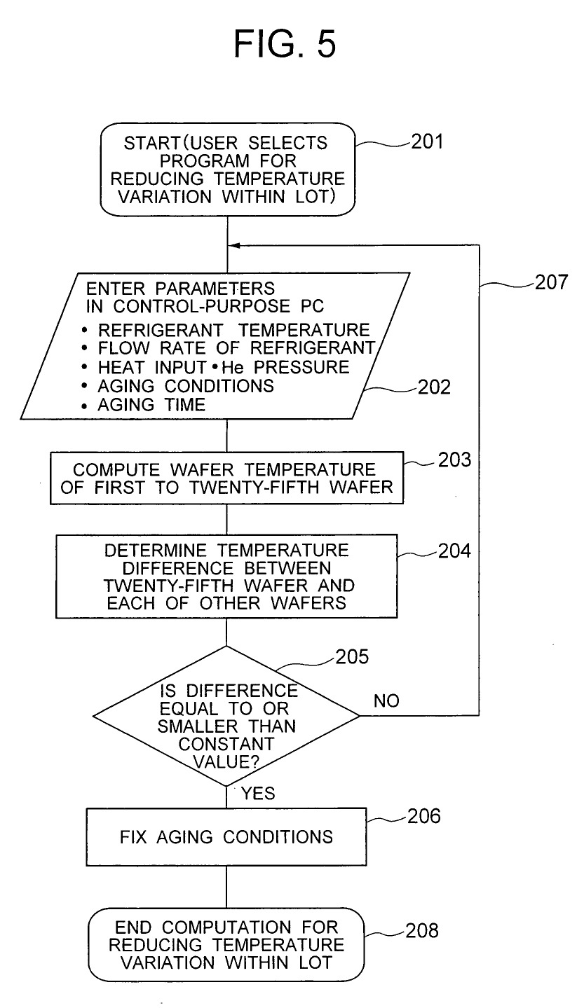

When the user selects this program to “Optimize aging conditions”, the control-purpose PC shifts to the processes according to the flowchart shown in FIG. 5 (step 201).

The processes according to the flowchart shown in FIG. 5 are fundamentally the same as those according to the flowchart shown in FIG. 3, but include the aging process added to the parameters for the computation of wafer temperature (step 202).

Under the conditions including this aging process added, the temperatures of the first to twenty-fifth wafers are calculated (step 203). The temperature difference between the twenty-fifth wafer and each of the other wafers is determined from the results of this computation (step 204).

Each of the temperature differences is compared with the reference value (step 205). If the difference is larger than the reference value, the program goes back to step 202, where the aging time is again newly set for a longer value or shorter value. Then, the operations in steps 203 and 204 are repeated. If the temperature difference between the twenty-fifth wafer and each of the other wafers is smaller than the reference value, this aging condition is fixed (step 206). Thereafter, this program for reducing temperature variation within lot is finished (step 208).

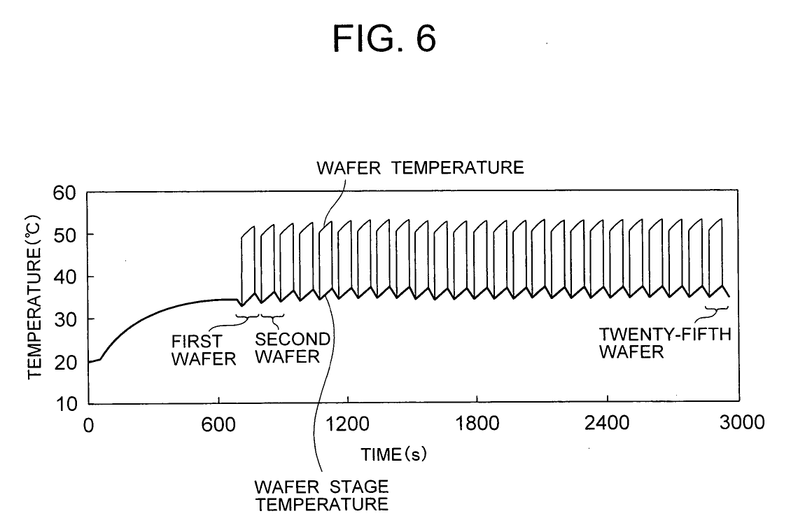

FIG. 6 shows the temperatures of wafers measured when the wafers are processed according to the flowchart shown in FIG. 5 in this embodiment. From FIG. 6, it will be understood that the temperature of the wafer stage gradually increases as in the prior art, but at this time the aging time taken until the first wafer is started to process is optimized so that the wafer stage temperature can be stabilized. Thus, the temperature of the first wafer is 51.6° C. and that of the twenty-fifth wafer is 52.6° C. That is, the temperature differences between the wafers are kept within 1° C.

Therefore, according to this embodiment, by processing the wafers according to the flowchart shown in FIG. 5, or optimizing the aging time, it is possible to maintain the temperatures of the wafers substantially constant. As a result, when the wafers are sequentially processed, reproducible etching process can be achieved.

By the way, although only the method of optimizing the aging time is used in the flowchart shown in FIG. 5, the biasing power, or the amount of heat input, at this time, cannot be sometimes much increased depending on the aging condition.

Thus, in this case, the ceramic plate 15 might not be heated enough to make the wafer stage temperature a value necessary for the aging. Thus, this case can use the program of adjusting rear-side He pressure given in the flowchart of FIG. 3 at the same time.

On the contrary, when the aging time becomes too long under the application of excessive heat, the wafer stage temperature sometimes rises too much at the time of processing the first wafer. This case can also use the program of adjusting rear-side He pressure shown in the flowchart of FIG. 3 at the same time.

Thus, in this embodiment, the program to “Adjust aging+rear-side He pressure” is provided as an option on the menu picture 100 shown in FIG. 10. When the user selects this program, the aging process is performed together with the adjustment of rear-side He pressure.

In this case, the time from the end of aging to the processing of the first wafer may be optimized. Thus, the wafer temperature variation within lot can be reduced.

Also, in this case, contrary to the processes using the flowchart shown in FIG. 3, there is a possibility that the rear-side He pressures of a few wafers beginning from the first wafer are required to set higher than those fixed by the user. At this time, the rear-side He pressure P (N) can be determined from the following equation (2).
P(N)=P1−(Pu−P1)(1−exp(−(N−1)/τ)) (2)

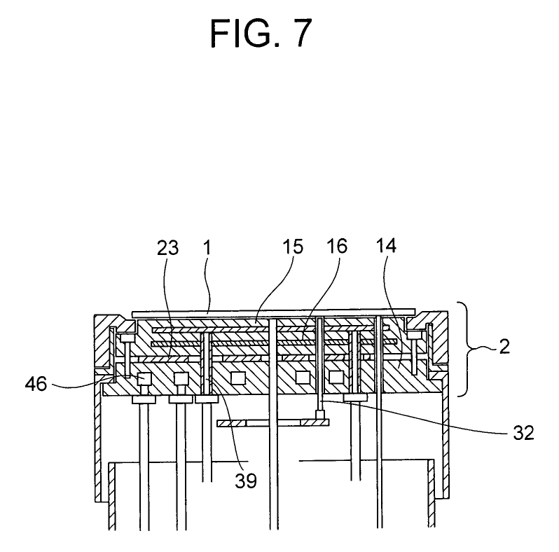

Next, it is assumed that the user selects the “program for reducing temperature variation within lot”, and then this time the program to “Optimize heater conditions” on the menu picture shown in FIG. 10. At this time, a new wafer stage 2 having a heater 16 buried within the ceramic plate 15 as shown in FIG. 7 as another embodiment is used in place of the wafer stage 2 shown in FIG. 1.

This heater 16 has a feeding electrode 39 provided, which is engaged with a plug for connection to a power supply so that electric power can be supplied from an external power supply through the electrode to the heater. Although the single electrode 39 is shown, actually two electrodes 39 are provided as a matter of course.

Thus, in this program to “Optimize heater conditions”, this heater 16 is used to heat the wafer stage for a constant time before the lot of wafers is processed, thereby keeping the temperature of each wafer constant over the first to twenty-fifth wafer.

At this time, if the heating value of the heater 16 is too high or if the heating time is too long, the temperature of the wafer stage probably becomes too high, thus excessively increasing the temperature of the first wafer.

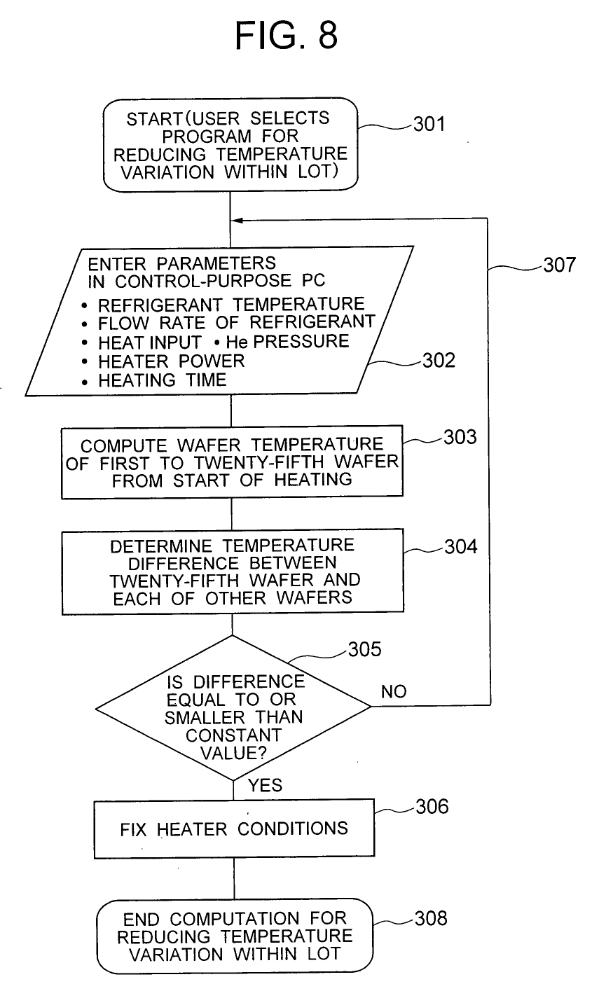

Thus, it is necessary to optimize the power and heating time of this heater 16. For this purpose, when this program to “Optimize heater conditions” is selected, the control-purpose PC executes the processes according to the flowchart shown in FIG. 8 (step 301).

The processes according to the flowchart of FIG. 8 are fundamentally the same as those according to the flowcharts shown in FIGS. 3 and 5, but have heater power and heating time added to the parameters for use in the computation of wafer temperatures (step 302).

Under these conditions, the temperatures of wafers up to the twenty-fifth wafer from the start of heating are calculated (step 303), the temperature difference of each wafer to the twenty-fifth wafer is determined from this result (step 304), and this difference is compared with the reference value (step 305).

If the temperature difference between the twenty-fifth wafer and each of the other wafers is larger than the reference value in this step 305, the program goes back to step 302, where the heater power and heating time are again newly fixed to increase or decrease (step 302). Then, the wafer temperature and temperature difference are repeatedly calculated (step 303, 304).

When the temperature difference of each wafer to the twenty-fifth wafer becomes less than the reference value, the program goes from step 305 to step 306, where the heater conditions are decided. Then, the program for reducing the temperature variation within lot is finished (step 308).

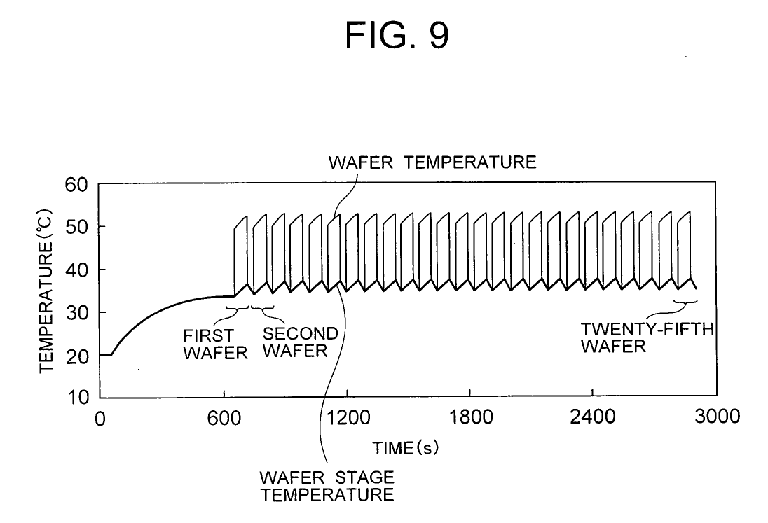

FIG. 9 shows the temperatures of the wafers according to the embodiment of FIG. 7 in which the program of FIG. 8 is executed and the heater conditions are optimized. At this time, the rear-side pressures of the first to twenty-fifth wafer are equal to 1 kPa, or constant over all wafers.

From FIG. 9, it will be seen that the wafer stage temperature gradually increases, but the temperatures of the first wafer and twenty-fifth wafer are 52.0° C. and 52.6° C., respectively, or the temperature difference being kept within 1° C.

In this case, since the heater 16 positively heats the wafer stage, the time in which the wafer stage temperature is stabilized at a predetermined temperature is decreased as is evident from the comparison with FIG. 6.

While the ceramic plate 15 has the heater 16 built therein in the embodiment of FIG. 7, this construction may be modified. For example, the heater structure may be made in contact with the ceramic plate or radiant heat from a lamp provided in the outside may be used in place of the above heater. Any one of those heaters should be selected according to its suitability to the apparatus.

Incidentally, the processes according to the flowchart of FIG. 8 do not consider the optimization of aging conditions mentioned with reference to the flowchart of FIG. 5, but may use it at the same time.

Thus, this embodiment provides the program to “Optimize aging+heater conditions” as an option on the menu picture 100 of FIG. 10. When the user selects this program, the process for the optimization of aging conditions is also performed at the same time.

This, however, is effective only when the wafer stage heating by aging is deficient. At this time, the optimum heater conditions are computed in consideration of the computation for the wafer stage heating by aging.

While this embodiment is constructed to be capable of selectively starting to execute the program for reducing temperature variation within lot in consideration of the user-friendliness, this function is not always required. The apparatus may be constructed to be capable of directly selecting from the menu shown in FIG. 10.

In the above embodiments, the data of wafer stage temperature measured by use of sheathed thermocouples is used to check if the results of the computation are correct. This data, however, can be used to control the helium pressure against the rear side of each wafer, thus adjusting the wafer temperature as described below.

The wafer stage temperature measured by the sheathed thermocouples, though it depends on the measurement position, is substantially equal to the surface temperature of the wafer stage shown in FIG. 2. From FIG. 2, it will be understood that, as the wafers are sequentially processed, the average temperature of each wafer is increased due to the temperature rise of the wafer stage. Thus, in order to cancel out this rise of temperature, the He pressure against the rear side of each wafer is adjusted to reduce the temperature difference between the wafer stage and each wafer, thereby making the average temperature of each wafer equal.

That is, in this embodiment, since the fluorescent temperature gauge is also used to monitor the wafer temperature, it is possible to determine the temperature of the wafer stage and the temperature difference between the wafer stage and each wafer. Since the temperature of the wafer stage just before the second wafer is started to process after the end of the first wafer processing is measured by the sheathed thermocouples the difference between the wafer stage temperature just before the second wafer is started and that just before the first wafer is started to process can be determined. Therefore, in order that the temperature of the second wafer can be made equal to that of the first wafer, the temperature difference between the second wafer and the wafer stage just before the second wafer is started to process is required to determine by subtracting the wafer stage temperature just before the second wafer is started to process from the wafer temperature just after the first wafer is processed. The rear-side He pressure necessary for this temperature difference can be calculated from the relation between the He pressure and thermal conductivity that is previously provided in the control-purpose computer. Accordingly, the average temperature of the second wafer can be made equal to that of the first wafer by processing the second wafer under this calculated He pressure. For the third and following wafers, the same procedure is used to adjust the He pressure, thereby reducing the temperature variation of the wafers.

This embodiment has treated the temperature measured on the rear side of the wafer stage as the typical temperature. This method can be said to be simple and easy when the thermal conductivity is large and when the temperature gradient does not occur in the thickness direction. However, when the material has a small thermal conductivity or when the amount of heat input is large enough to cause a temperature gradient in the thickness direction, the temperature difference between the surface and rear side of the wafer stage becomes large. Thus, the temperature of the rear side of the wafer stage will be sometimes inadequate for the typical temperature. In such case, if the control-purpose computer corrects the measured temperature data, the same function can be achieved, and thus the same effect can be expected.

It should be further understood by those skilled in the art that although the foregoing description has been made on embodiments of the invention, the invention is not limited thereto and various changes and modifications may be made without departing from the spirit of the invention and the scope of the appended claims.

1. A wafer processing apparatus in which a plurality of semiconductor wafers are sequentially placed on a wafer stage and processed as a lot using plasma, said apparatus comprising:
a calculator which calculates, before starting to process the sequentially placed semiconductor wafers, a temperature of each semiconductor wafer during each of the sequential processes, and plural conditions of processing operations of the apparatus for the each of the sequential processes so that the temperature of each semiconductor wafer falls within a predetermined range;
the plural conditions of processing operations of the apparatus including at least one of a pressure of a heat-conductive gas introduced between each of the semiconductor wafers and the wafer stage, heating by a heater disposed in the wafer stage, and an aging time applied before a start of the sequential processes as the lot; and
a controller which adjusts one of the plural conditions of the processing operations of the apparatus during each of the sequential processes based on results of calculations of the calculator.

2. A wafer processing apparatus according to claim 1, further comprising:
a detector which detects a temperature of the wafer stage, wherein the controller adjusts one of the plural conditions of processing operations during each of the sequential processes on a basis of an output from the detector.

3. A wafer processing apparatus according to claim 2, wherein said detector is any one of a sheathed thermocouple, a fluorescent temperature gauge and a thermistor.
